(19) United States
(12) Patent Application Publication
(10) Pub. No.: US 2016/0187435 A1
(43) Pub. Date: Jun. 30, 2016

(54) COOLING SYSTEM AND METHOD FOR A MAGNETIC RESONANCE IMAGING DEVICE

(71) Applicant: GENERAL ELECTRIC COMPANY, Schenectady, NY (US)

(72) Inventors: LONGZHI JIANG, Florence, SC (US); Yuri Lvovsky, Florence, SC (US); Stuart Paul Feltham, Florence, SC (US)

(73) Assignee: GENERAL ELECTRIC COMPANY, Schenectady, NY (US)

(21) Appl. No.: 14/584,069

(22) Filed: Dec. 29, 2014

(51) Int. Cl. G01R 33/34

(52) U.S. Cl. CPC G01R 33/3403; G01R 33/34023

(57) ABSTRACT

A cooling system includes a first cooling loop having a first cooling fluid configured for circulation therethrough and a second cooling loop having a second cooling fluid configured for circulation therethrough. The first cooling loop is in thermal communication with the superconducting magnet and is configured to provide primary cooling for the magnet, and the second cooling loop is in thermal communication with the superconducting magnet and is configured to provide secondary cooling for the magnet.

### BACKGROUND

1. Technical Field

Embodiments of the invention relate generally to magnetic resonance imaging and, more specifically, to a cooling system and method for a magnetic resonance imaging device.

2. Discussion of Art

Magnetic resonance imaging (MRI) machines work by generating a very strong magnetic field using a superconducting magnet which consists of many coils or windings of wires through which a current is passed. Creating a strong magnetic field is accomplished using superconductivity, which involves reducing the resistance in the current-carrying conductors to practically zero by cooling them to ultra-low temperatures below the superconducting limits This may be achieved by immersing the coils in a bath of liquid cryogen, such as liquid helium, and/or by circulating liquid cryogen within cooling loops adjacent to, or through, the coils, or by providing solid conductive pathways that allow to withdraw heat from the coils.

As will be readily appreciated, maintaining an ultra-low temperature in the coils is necessary for proper operation of the MRI machine. However, during ramp, considerable heat may be generated, mainly in leads, switches and heaters, which is transferred to and deposited in the cold mass assembly. During persistent operation, the heat is introduced either via solid conduction components, such as current leads, penetrations or suspension elements, or by radiation or residual gas conduction coming from components of cryostat assembly with higher temperature. The heat coming to the cold mass that contains the coils may lead to boil-off or evaporation of the cryogen, requiring replenishment.

Considerable research and development efforts have therefore been directed at minimizing the need to replenish the boiling cryogen. This has led to the use of cryogen gas recondensing systems that utilize a mechanical refrigerator or cryocooler, also known as a cold head, to cool the cryogen gas and recondense it back to liquid cryogen for reuse.

However, from time to time the cooling may be interrupted in the MRI devices located in clinical environment. That happens, for example, when it becomes necessary to remove the cryocooler for replacement and/or servicing. It is desirable to accomplish this without discontinuing superconducting operation of the magnet because of the time and expense resulting from relatively long “down-time” and subsequent ramping up period of bringing the magnet back to superconducting operation. Replacement of the cryocooler must therefore be effected in the period after a problem or service need is detected and before superconducting operation ceases.

Another condition when cooling power ceases to be provided to the superconducting magnet is a power outage. During the outage, the non-operating coldhead introduces thermal short that may input additional heat to the superconducting system.

This period after the cooling power is interrupted and before the superconducting operation ceases is known as the ride-through period, during which the final period of superconducting magnet operation and helium boil-off continues before quenching of the superconducting magnet. Indeed, for magnets with closed helium inventory, i.e., low cryogen type magnets, the duration of tolerable power outage, coldhead service or ramp profile is limited by the volume of accumulated liquid helium that boils off or evaporates during the above conditions with extra heat load.

It is therefore desirable to be able to extend the ride-through period to provide sufficient time for detection and correction of a problem such as by replacement of a cryocooler, to withstand a power outage, and also to avoid the possibility of peak temperatures being generated by superconducting operation quench which could exceed the critical temperature of the superconducting wires with which the magnet coils are wound.

### BRIEF DESCRIPTION

In an embodiment, a cooling system for a superconducting magnet is provided. The cooling system includes a first cooling loop having a first cooling fluid configured for circulation therethrough and a second cooling loop having a second cooling fluid configured for circulation therethrough. The first cooling loop is in thermal communication with the superconducting magnet and is configured to provide primary cooling for the magnet, and the second cooling loop is in thermal communication with the superconducting magnet and is configured to provide secondary cooling for the magnet.

In an embodiment, an imaging apparatus is provided. The imaging apparatus includes at least one coil support shell, a plurality of superconducting magnet coils supported by the at least one coil support shell, a first cooling loop having a first cryogen configured for circulation therethrough, the first cooling loop being in thermal communication with the magnet coils and being configured to provide primary cooling for the magnet coils, a cryocooler fluidly coupled with the first cooling loop forming a closed circulation cooling system, and a second cooling loop having a second cooling fluid configured for circulation therethrough, the second cooling loop being in thermal communication with the magnet coils and being configured to provide secondary cooling for the magnet during a downtime of the first cooling loop.

In another embodiment, a method of cooling a superconducting magnet is provided. The method includes circulating a first cryogen through a first cooling loop in thermal communication with the superconducting magnet and circulating the second cryogen through a second cooling loop in thermal communication with the superconducting magnet.

### DRAWINGS

The present invention will be better understood from reading the following description of non-limiting embodiments, with reference to the attached drawings, wherein below:

FIG. 1 is side, cross-sectional view of a cooling system for a superconducting magnetic of a magnetic resonance imaging machine in accordance with an embodiment of the present invention.

FIG. 2 is a schematic illustration of the system of FIG. 1, shown in connection with a magnetic resonance imaging machine.

FIG. 3 is a simplified schematic illustration of a cryostat of the magnetic resonance imaging apparatus of FIG. 2, showing the positioning of cryogen storage tanks.

FIG. 4 is a simplified schematic illustration a secondary cooling loop of the cooling system of FIG. 1, in accordance with an embodiment of the present invention.

FIG. 5 is a simplified schematic illustration a secondary cooling loop of the cooling system of FIG. 1, in accordance with another embodiment of the present invention.

### DETAILED DESCRIPTION

Reference will be made below in detail to exemplary embodiments of the invention, examples of which are illustrated in the accompanying drawings. Wherever possible, the same reference characters used throughout the drawings refer to the same or like parts. Although embodiments of the present invention are described as intended for use with superconducting magnets embodied in MRI machines, the present invention may also be used for the cooling of superconducting magnets, generally, irrespective of their specific end use. The superconducting magnets may also be implemented in other types of medical imaging devices, as well as non-medical imaging devices.

As used herein, “thermally coupled,” “thermally connected” and “thermal communication” means that two physical systems or components are associated in such a manner that thermal energy and heat may be transferred between such systems or components. For example, such thermal communication can be achieved, without loss of generality, by snug contact between surfaces at an interface; one or more heat transfer materials or devices between surfaces; a connection between solid surfaces using a thermally conductive material system, or other structures with high thermal conductivity between the surfaces (e.g., heat exchangers); other suitable structures; or combinations of structures. Substantial thermal communication can take place between surfaces that are directly connected (e.g., contact each other) or indirectly connected via one or more interface materials. Thermal communication be conductive, convective, radiative, or any combination thereof. As also used herein, “fluid communication” or “fluidly coupled” is meant to refer to a coupling through a channel or conduit that allows fluids (e.g., gases and liquids) to flow therethrough or therebetween, at least at desired times. As used herein, “fluidly isolated” means that fluids are not permitted to flow or pass between respective elements, components, systems, etc.

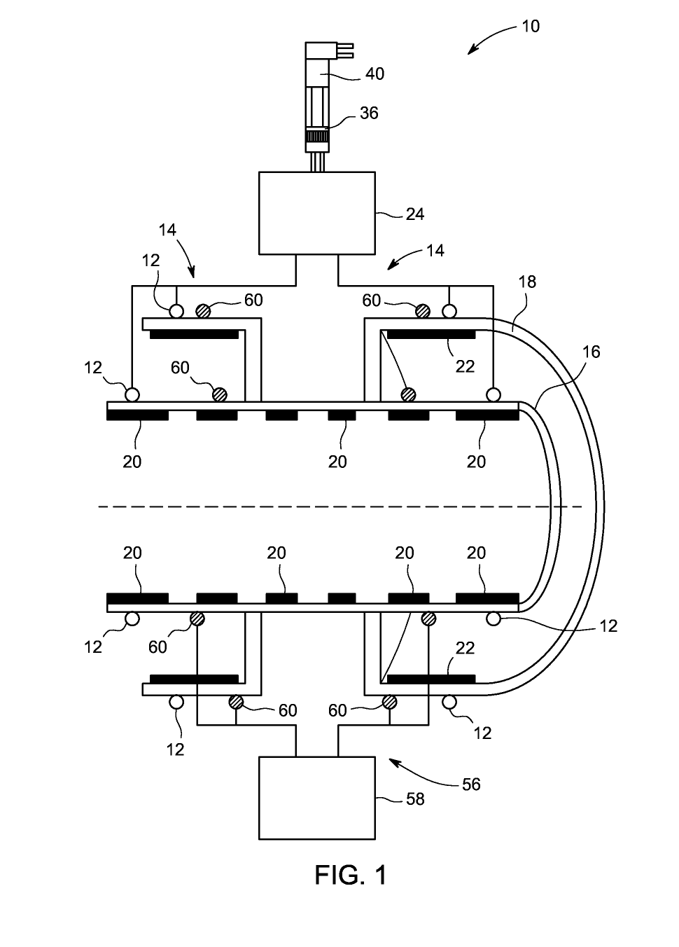

Referring now to FIG. 1, a cooling system 10 for a superconducting magnet of a MRI machine is illustrated. As shown therein, the cooling system 10 includes a plurality of cooling tubes 12, or other suitable cooing paths, with liquid helium circulating within the cooling tubes 12. The cooling tubes 12 define a primary cooling loop 14. The cooling tubes 12 are thermally coupled to a main former or support shell 16 and, in an embodiment, may also be thermally coupled to a shield former or support shell 18 that encompasses the main former 16. The main former 16 and shield former 18 support or maintain the position of main MRI magnet coils 20 and shield MRI magnet coils 22, respectively, in a manner heretofore known in the art. For example, the main magnet coils 20 may be shrink fit and bonded inside the main former 16, which may be a cylindrical metal coil former, to thereby provide thermal contact therebetween. Likewise the shield magnet coils 22 may be shrink fit and bonded inside the shield former 18, which may be a cylindrical metal coil former, to thereby provide thermal contact therebetween. Other types of coils may be provided, for example, epoxied coils. In an embodiment the main magnet coils 20 and the shield magnet coils 22 may be formed from any material capable of producing a superconducting magnet, such as from Niobium-titanium (NbTi) or Niobium-tin (Nb₃Sn).

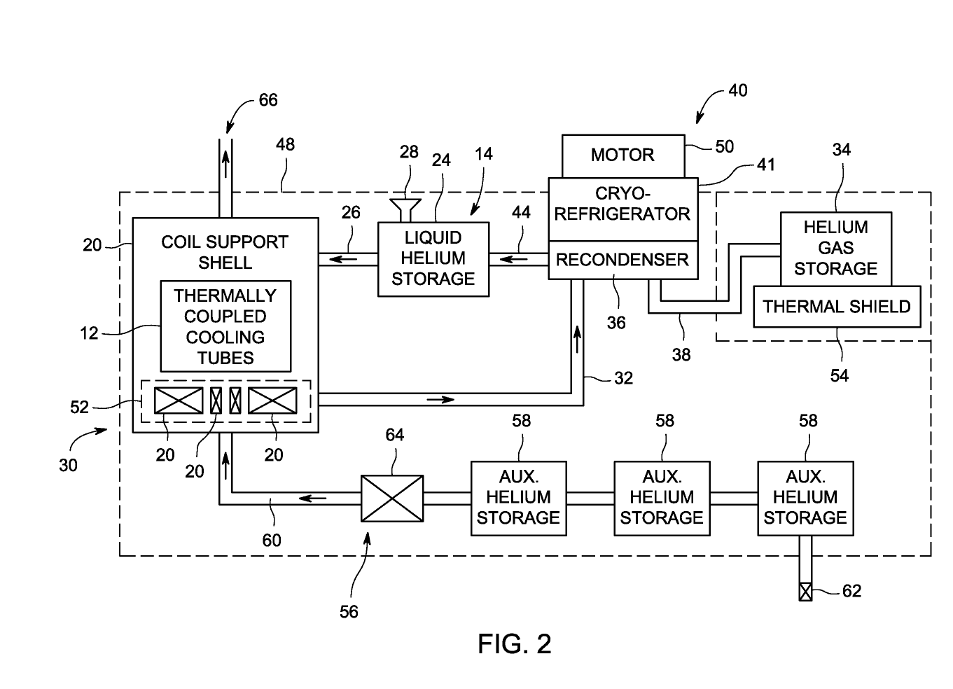

As further illustrated in FIG. 2, the various embodiment of the present invention may be implemented as part of an MRI magnet system 30, such as those commonly known in the art, wherein the cooling may be provided via a two stage cooling arrangement. It should be noted that like numerals represent like parts throughout the Figures.

The coil formers 16, 18, which may be formed from a thermally conductive material (e.g., aluminum), provide a cold mass support structure that maintain the position of or support the magnetic coils 20, 22, respectively. The cooling tubes 12, which may be formed from any suitable metal (e.g., copper, stainless steel, aluminum, etc.) are in fluid communication with a primary, or first, liquid cryogen storage tank 24. The cryogen storage tank 24 contains the liquid cryogen used in the closed loop cooling system 10 to cool the magnet coils 20, 22. In an embodiment, the cryogen is liquid helium. The fluid communication between the cooling tubes 12 and the liquid helium storage tank(s) 24 may be provided by one or more fluid passageways 26 (e.g., fluid tubes, conduits, etc.). Thus, the storage tank 24 provides the liquid helium that flows through the cooling tubes 12 to cool the magnet coils 20, 22.

In the illustrated embodiment, the primary cooling loop 14 contains no venting. However, in some embodiments, venting may be provided, for example, using a vent 28 having a very high venting pressure level. For example, in some embodiments the vent 28 is configured to provide venting at the highest pressure the system can handle without failure (or within a predefined range thereof). However, different pressure levels may be provided in embodiments that include the vent 28, which may be based on system requirements, regulatory requirements, etc.

As best illustrated in FIG. 2, in an embodiment, the cooling tubes 12 may be in fluid communication with a vapor return manifold or passageway 32, which may be in fluid communication with a helium gas storage system 34 through a recondenser 36. The helium gas storage system 34, which may be formed from one or more helium gas storage tanks contains helium gas received as helium vapor from the cooling tubes 12 that removes heat from the magnet coils 20, 22 and forms part of the closed loop cooling system. The fluid communication between the recondenser 36 and the helium gas storage system 34 may be provided via one or more passageways 38.

The helium gas storage system 34 is in fluid communication with a cryorefrigerator 40 that includes the recondenser 36, which fluid communication may be provided via one or more fluid passageways 38. In various embodiments, the recondenser 36 may draw helium gas from the helium gas storage system 34 that operates to form a free convection circulation loop to cool the magnet coils 20, 22 and coil support shells 16, 18 to a cryogenic temperature, as well as fills the reservoir 24 with liquid helium via one or more passageways 44.

The cryorefrigerator 40, which may be a coldhead or other suitable cryocooler, extends through a cryostat 48, which may include a vacuum vessel, and which contains therein the MRI magnet system 30 and the cooling components of the various embodiments. The cryorefrigerator 40 may extend within a sleeve or housing, referred to as coldhead sleeve 41. Thus, the cold end of the cryorefrigerator 40 may be positioned within the sleeve without affecting the vacuum within the vacuum vessel. The cryorefrigerator 40 is inserted (or received) and secured within the sleeve using any suitable means, such as one or more flanges and bolts, or other suitable means. Moreover, a motor 50 of the cryorefrigerator 40 is provided outside the vacuum vessel and/or cryostat 48.

As illustrated in FIG. 2, the cryorefrigerator 40 in various embodiments includes the recondenser 36 at a lower end of the cryorefrigerator 40 that recondenses boiled off helium gas received from the vapor return manifold/passageway 32 in parallel with the helium gas storage system 34. The recondenser 36 allows for transferring boiled off helium gas from the helium gas storage system 34 to the liquid helium reservoir 24.

The magnet coils 20, which in various embodiments are molded coils, form a main superconducting magnet 52 that is controlled during operation of the MRI system as is known in the art to acquire MRI image data. Additionally, during operation of the MRI system, liquid helium cools the superconducting magnet 52. The superconducting magnet 52 may be cooled, for example, to a superconducting temperature, such as 4.2 Kelvin (K). The cooling process may include the recondensing of boiled off helium gas to liquid by the recondenser 36 and returned to the liquid helium tank 24 as described herein.

The various embodiments also provide a thermal shield 54, which may be in thermal contact with the helium gas storage system 34. In various embodiments, the MRI magnet system 30 and the cooling components of the various embodiments are provided within the cryostat 48 and vacuum vessel that includes the thermal shield 54 therein and/or therebetween.

As further illustrated in FIGS. 1 and 2, the system 10 further includes a secondary cooling loop 56 that is configured to provide secondary or auxiliary cooling of the magnet coils 20, 22 in the manner described hereinafter. As shown therein, the secondary cooling loop 56 includes one or more auxiliary storage tanks 58 filled with a secondary supply of a cryogen which, in an embodiment, may be liquid helium, and a plurality of auxiliary cooling tubes 60, or other suitable cooing paths, in fluid communication with the storage tanks 58 for circulating the liquid helium throughout the cooling loop 56. Like cooling tubes 12, auxiliary cooling tubes 60 may be formed from any suitable metal (e.g., copper, stainless steel, aluminum, etc.). The secondary cooling loop 56 is fluidly isolated from the primary cooling loop 14.

In an embodiment, the cooling tubes 60 of the secondary cooling loop 56 may be thermally coupled to at least one of the main former or support shell 16, the shield former or support shell 18, the thermal shield 54 and/or the coldhead sleeve 41. As shown in FIG. 2, the secondary cooling loop 56 may also include a charge line 62 configured with a valve to allow an operator or technician to refill the auxiliary storage tanks 58 with liquid helium cooled to at least 4.2K from outside the MRI magnet system 30. The tanks 58 are configured to be pumped down prior to filling. In addition, a valve 64 is provided to allow the liquid helium within the storage tanks 58 to be selectively released into cooling tubes 60. The valve 64 may be any type of valve known in the art and may be manually actuated or controlled via a control unit (not shown) to allow for the selective release of liquid helium from tanks 58. As illustrated in FIG. 2, the secondary cooling loop 56 includes an outlet 66 that permits venting of the tanks 58 and cooling loop 56, as discussed below.

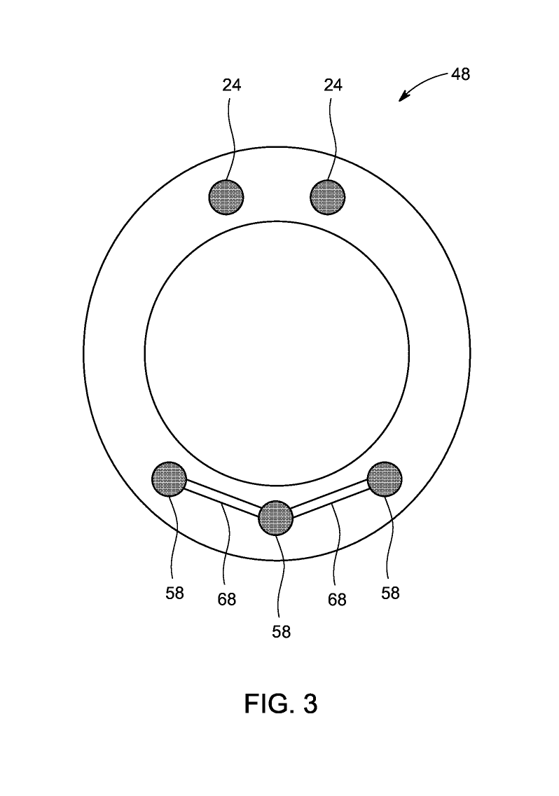

As best shown in FIG. 3, the tanks 58 are fluidly coupled to one another via tubes or passageways 68, which ensure that they share the same pressure. The tanks 58 may be located within the cryostat 48, at the bottom thereof and opposite the primary storage tanks 24. In an embodiment, the tanks 58 may be operable in either a high pressure environment or at atmospheric pressure.

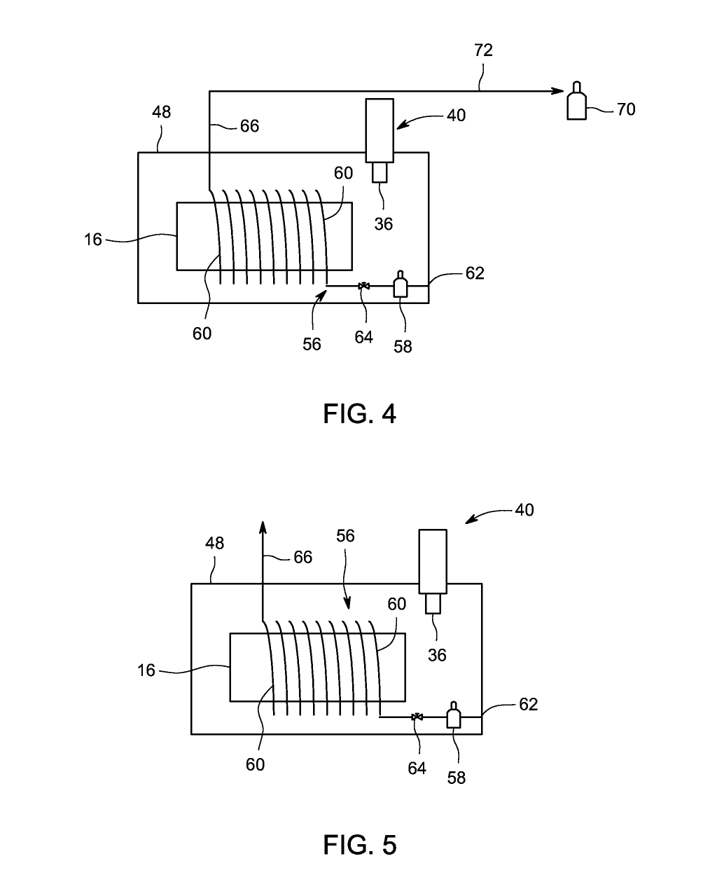

Turning now to FIG. 4, in an embodiment, the tanks 58 and cooling loop 56 are vented to another tank external to the MRI magnet system 30 to recover the helium after passing through cooling tubes 60. In connection with this, the cooling loop 56 may include one or more recovery tanks 70 that are in fluid communication without outlet 66 via passageway 72.

With reference to FIG. 5, in another embodiment, the tanks 58 may be vented directly to atmosphere, through outlet 66. For example, the outlet may be coupled to a vent line of a building in which the MRI magnet system 30 is located such that the helium gas produced from liquid-helium boil-off may be released to the atmosphere.

In an embodiment, the tanks 58 may be sized, or any number of tanks used, to provide almost any ride-through duration desired. As will be readily appreciated, the boil-off rate of liquid helium during power interruption or coldhead changeout (i.e., when the primary cooling loop 14 is not providing cooling) is about 2 liters per hour. The number of tanks or volume of helium utilized can easily be determined in dependence upon the number of hours of ride-through desired. For example, where two days (48 hours) of ride-through are desired, the total amount of liquid helium needed in the secondary storage tanks 58 to provide for such ride-through is approximately 100 liters.

In operation, the cooling system 10 of the present invention is able to extend the ride-through time under coldhead change-out and periods of power interruption by the provision of a secondary cooling loop 56 supplied with liquid helium from auxiliary tanks 58. In particular, during coldhead changeout or a power interruption, magnet temperature and/or pressure will typically begin to rise because the circulation of cooling fluid within the primary loop 14 has been paused. To prevent or stem this rise, the auxiliary tanks 58 provide an secondary supply of liquid helium which is passed through secondary cooling tubes 60 that are in thermal communication with the main former 16, the shield former 18, the thermal shield 54 and/or the coldhead sleeve 41. As will be readily appreciated, the sensible heat from the liquid helium passing through the cooling tubes 60 will remove the magnet heat due to power interruption and/or coldhead changeout. Accordingly, the present invention is therefore able to maintain the magnet coils 20, 22 at low temperature to prevent quenching, until power the coldhead changeout is complete and/or power is restored.

In contrast to existing systems, the cooling system 10 of the present invention provides for a closed-cryogen-inventory magnet with improved ride-through times and faster magnet cool-down. In particular, the present invention therefore provides a dual cooling loop cooling system for a superconductive magnet whereby the use of the second cooling loop effectively extends the ride-through period of the magnet by removing heat from the magnet via the circulation of an auxiliary supply of liquid helium through secondary cooling tubes.

In an embodiment, a cooling system for a superconducting magnet is provided. The cooling system includes a first cooling loop having a first cooling fluid configured for circulation therethrough and a second cooling loop having a second cooling fluid configured for circulation therethrough. The first cooling loop is in thermal communication with the superconducting magnet and is configured to provide primary cooling for the magnet, and the second cooling loop is in thermal communication with the superconducting magnet and is configured to provide secondary cooling for the magnet. In an embodiment, the second cooling loop includes at least one storage tank configured to store the second cooling fluid and a plurality of secondary cooling tubes for circulating the second cooling fluid. In an embodiment, the cooling system is integrated in an MRI magnet system, and the secondary cooling tubes are thermally coupled to at least one of a support shell supporting coils of the magnet, a thermal shield or a coldhead sleeve of the MRI magnet system. In an embodiment, the second cooling loop includes an outlet in fluid communication with a recovery tank located external to the MRI magnet system. In an embodiment, the second cooling loop includes an outlet in fluid communication with atmosphere. In an embodiment, the at least one storage tank is a plurality of storage tanks, the plurality of storage tanks being fluidly coupled to one another. In an embodiment, the second cooling loop includes a charge line configured to allow for selective filling of the at least one storage tank with the second cooling fluid. In an embodiment, the second cooling loop includes a valve configured to selectively permit release of the second cooling fluid from the at least one storage tank into the cooling tubes. In an embodiment, the at least one storage tank is housed inside a cryostat of the MRI magnet system. In an embodiment, the second cooling fluid is liquid helium. In an embodiment, the first cooling fluid is liquid helium.

In an embodiment, an imaging apparatus is provided. The imaging apparatus includes at least one coil support shell, a plurality of superconducting magnet coils supported by the at least one coil support shell, a first cooling loop having a first cryogen configured for circulation therethrough, the first cooling loop being in thermal communication with the magnet coils and being configured to provide primary cooling for the magnet coils, a cryocooler fluidly coupled with the first cooling loop forming a closed circulation cooling system, and a second cooling loop having a second cooling fluid configured for circulation therethrough, the second cooling loop being in thermal communication with the magnet coils and being configured to provide secondary cooling for the magnet during a downtime of the first cooling loop. In an embodiment, the downtime of the first cooling loop is during a coldhead changeout operation or a power interruption. In an embodiment, the second cooling loop includes at least one storage tank configured to store the second cooling fluid and a plurality of secondary cooling tubes for circulating the second cooling fluid. In an embodiment, the imaging apparatus includes a coldhead sleeve housing the cryocooler, and a thermal shield. The secondary cooling tubes may be thermally coupled to at least one of the coil support shell, the thermal shield or the coldhead sleeve. In an embodiment, the second cooling loop includes an outlet in fluid communication with a recovery tank located external to the imaging apparatus. In an embodiment, the second cooling loop includes an outlet in fluid communication with atmosphere. In an embodiment, the at least one storage tank is a plurality of storage tanks, and the plurality of storage tanks are fluidly coupled to one another to permit equalization of pressure between the plurality of storage tanks. In an embodiment, the second cooling loop includes a charge line configured to allow for selective filling of the at least one storage tank with the second cooling fluid from external to the imaging apparatus. In an embodiment, the second cooling loop includes a valve configured to selectively permit release of the second cooling fluid from the at least one storage tank into the cooling tubes. In an embodiment, the second cooling fluid is liquid helium.

In another embodiment, a method of cooling a superconducting magnet is provided. The method includes circulating a first cryogen through a first cooling loop in thermal communication with the superconducting magnet and circulating the second cryogen through a second cooling loop in thermal communication with the superconducting magnet. In an embodiment, the second cooling loop is fluidly isolated from the first cooling loop. In an embodiment, the second cryogen is liquid helium. In an embodiment, the method also includes the step of recovering at least one of the liquid helium and helium gas from the second cooling loop in a recovery tank.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope.

While the dimensions and types of materials described herein are intended to define the parameters of the invention, they are by no means limiting and are exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, terms such as “first,” “second,” “third,” “upper,” “lower,” “bottom,” “top,” etc. are used merely as labels, and are not intended to impose numerical or positional requirements on their objects. Further, the limitations of the following claims are not written in means-plus-function format and are not intended to be interpreted based on 35 U.S.C. §122, sixth paragraph, unless and until such claim limitations expressly use the phrase “means for” followed by a statement of function void of further structure.

This written description uses examples to disclose several embodiments of the invention, including the best mode, and also to enable one of ordinary skill in the art to practice the embodiments of invention, including making and using any devices or systems and performing any incorporated methods. The patentable scope of the invention is defined by the claims, and may include other examples that occur to one of ordinary skill in the art. Such other examples are intended to be within the scope of the claims if they have structural elements that do not differ from the literal language of the claims, or if they include equivalent structural elements with insubstantial differences from the literal languages of the claims.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

Since certain changes may be made in the above-described invention, without departing from the spirit and scope of the invention herein involved, it is intended that all of the subject matter of the above description or shown in the accompanying drawings shall be interpreted merely as examples illustrating the inventive concept herein and shall not be construed as limiting the invention.

What is claimed is:

1. A cooling system for a superconducting magnet, comprising:
a first cooling loop having a first cooling fluid configured for circulation therethrough, the first cooling loop being in thermal communication with the superconducting magnet and being configured to provide primary cooling for the magnet; and
a second cooling loop having a second cooling fluid configured for circulation therethrough, the second cooling loop being in thermal communication with the superconducting magnet and being configured to provide secondary cooling for the magnet.

2. The cooling system of claim 1, wherein:
the second cooling loop includes at least one storage tank configured to store the second cooling fluid and a plurality of secondary cooling tubes for circulating the second cooling fluid.

3. The cooling system of claim 2, wherein:
the cooling system is integrated in an MRI magnet system; and
the secondary cooling tubes are thermally coupled to at least one of a support shell supporting coils of the magnet, a thermal shield or a coldhead sleeve of the MRI magnet system.

4. The cooling system of claim 3, wherein:
the second cooling loop includes an outlet in fluid communication with a recovery tank located external to the MRI magnet system.

5. The cooling system of claim 3, wherein:
the second cooling loop includes an outlet in fluid communication with atmosphere.

6. The cooling system of claim 3, wherein:
the at least one storage tank is a plurality of storage tanks, the plurality of storage tanks being fluidly coupled to one another.

7. The cooling system of claim 3, wherein:
the second cooling loop includes a charge line configured to allow for selective filling of the at least one storage tank with the second cooling fluid.

8. The cooling system of claim 3, wherein:
the second cooling loop includes a valve configured to selectively permit release of the second cooling fluid from the at least one storage tank into the cooling tubes.

9. The cooling system of claim 3, wherein:
the at least one storage tank is housed inside a cryostat of the MRI magnet system.

10. The cooling system of claim 3, wherein:
the second cooling fluid is liquid helium.

11. The cooling system of claim 9, wherein:
the first cooling fluid is liquid helium.

12. An imaging apparatus, comprising:
at least one coil support shell;
a plurality of superconducting magnet coils supported by the at least one coil support shell;
a first cooling loop having a first cryogen configured for circulation therethrough, the first cooling loop being in thermal communication with the magnet coils and being configured to provide primary cooling for the magnet coils;
a cryocooler fluidly coupled with the first cooling loop forming a closed circulation cooling system; and
a second cooling loop having a second cooling fluid configured for circulation therethrough, the second cooling loop being in thermal communication with the magnet coils and being configured to provide secondary cooling for the magnet during a downtime of the first cooling loop.

13. The imaging apparatus of claim 12, wherein:
the downtime of the first cooling loop is during a coldhead changeout operation or a power interruption.

14. The imaging apparatus of claim 12, wherein:
the second cooling loop includes at least one storage tank configured to store the second cooling fluid and a plurality of secondary cooling tubes for circulating the second cooling fluid.

15. The imaging apparatus of claim 14, wherein:
the imaging apparatus includes a coldhead sleeve housing the cryocooler, and a thermal shield; and
wherein the secondary cooling tubes are thermally coupled to at least one of the coil support shell, the thermal shield or the coldhead sleeve.

16. The imaging apparatus of claim 14, wherein:
the second cooling loop includes an outlet in fluid communication with a recovery tank located external to the imaging apparatus.

17. The imaging apparatus of claim 14, wherein:
the second cooling loop includes an outlet in fluid communication with atmosphere.

18. The imaging apparatus of claim 14, wherein:
the at least one storage tank is a plurality of storage tanks, the plurality of storage tanks being fluidly coupled to one another to permit equalization of pressure between the plurality of storage tanks.

19. The imaging apparatus of claim 14, wherein:
the second cooling loop includes a charge line configured to allow for selective filling of the at least one storage tank with the second cooling fluid from external to the imaging apparatus.

20. The imaging apparatus of claim 14, wherein:
the second cooling loop includes a valve configured to selectively permit release of the second cooling fluid from the at least one storage tank into the cooling tubes.

21. The imaging apparatus of claim 14, wherein:
the second cooling fluid is liquid helium.

22. A method of cooling a superconducting magnet, the method comprising the steps of:
circulating a first cryogen through a first cooling loop in thermal communication with the superconducting magnet; and
circulating a second cryogen through a second cooling loop in thermal communication with the superconducting magnet.

23. The method according to claim 22, wherein:
the second cooling loop is fluidly isolated from the first cooling loop.

24. The method according to claim 23, wherein:
the second cryogen is liquid helium.

25. The method according to claim 23, further comprising the step of:
recovering at least one of the liquid helium and helium gas from the second cooling loop in a recovery tank.
